(19) United States
(12) Patent Application Publication
(10) Pub. No.: US 2011/0070859 A1
(43) Pub. Date: Mar. 24, 2011

(54) LOW NOISE AMPLIFIER AND RADIO FREQUENCY SIGNAL RECEIVER

(76) Inventors: Tsung-Yuan CHIANG, Taipei County (TW); Nien-An Kao, Taipei County (TW)

(21) Appl. No.: 12/860,165

(22) Filed: Aug. 20, 2010

(30) Foreign Application Priority Data
Sep. 18, 2009 (TW) 98217228

(51) Int. Cl. H04B 1/16; H03F 3/16

(52) U.S. Cl. 455/341; 330/277

(57) ABSTRACT

The invention provides a low noise amplifier. The low noise amplifier includes a first transistor, a second transistor, and a first resistor. The first transistor has a gate to receiving a radio frequency input signal, wherein the source of the first transistor is coupled to a ground voltage. The second transistor has a drain to output a radio frequency output signal, wherein the gate of the second transistor is coupled to a first reference voltage. The first resistor is coupled between the drain of the first transistor and the source of the second transistor.

### CROSS REFERENCE TO RELATED APPLICATIONS

This application claims priority of Taiwan Patent Application No. 98217228, filed on Sep. 18, 2009, the entirety of which is incorporated by reference herein.

### BACKGROUND OF THE INVENTION

1. Field of the Invention

The invention relates to radio frequency signal receivers, and more particularly to low noise amplifiers (LNA) of radio frequency signal receivers.

2. Description of the Related Art

A low noise amplifier is an electronic amplifier used in a communications system for amplifying feeble radio frequency signals captured by an antenna. Conventionally, the low noise amplifier is disposed close to the antenna to reduce signal attenuation due to signal transmission between the low noise amplifier and the antenna. A radio frequency signal receiver ordinarily comprises a low noise amplifier located in the front-end circuit of the receiver. For example, a Bluetooth system comprises a low noise amplifier for signal amplification.

A noise figure of a low noise amplifier determines noise amplitude of a radio frequency signal received by a radio frequency signal receiver. A low noise amplifier therefore must have a high voltage gain and a low noise figure to amplify the small signal components within the operative range of a radio frequency signal to improve quality of the output signal. Circuit properties of a low noise amplifier determine quality of a radio frequency signal received by a radio frequency signal receiver.

Because a radio frequency signal receiver is often installed in a portable device, and the power of the portable device is supplied by batteries, a radio frequency signal receiver must be designed with low power consumption to extend a lifespan of the batteries. When a conventional low noise amplifier receives a large signal, the power consumption of the conventional low noise amplifier is far greater than that of the conventional low noise amplifier for amplifying a small signal. If the current flowing through the conventional low noise amplifier is reduced, the performance of the conventional low noise amplifier is degraded. Thus, a low nose amplifier which has both reduced power consumption and good performance is required.

### BRIEF SUMMARY OF THE INVENTION

The invention provides a low noise amplifier. The low noise amplifier comprises a first transistor, a second transistor, and a first resistor. The first transistor has a gate to receiving a radio frequency input signal, wherein the source of the first transistor is coupled to a ground voltage. The second transistor has a drain to output a radio frequency output signal, wherein the gate of the second transistor is coupled to a first reference voltage. The first resistor is coupled between the drain of the first transistor and the source of the second transistor.

The invention provides a low noise amplifier. In one embodiment, the low noise amplifier comprises a first transistor, a first resistor, a second transistor, and a switchable load element. The first transistor is coupled between a first node and a ground voltage, wherein the gate of the first transistor is coupled to a second node for receiving a radio frequency input signal. The first resistor is coupled between the first node and a third node. The second transistor is coupled between a fourth node and the third node, wherein the gate of the second transistor is coupled to a first reference voltage, wherein the fourth node outputs a radio frequency output signal. The switchable load element is coupled between a voltage source and the fourth node, wherein the impedance of the switchable load element is adjustable.

The invention provides a radio frequency signal receiver. In one embodiment, the radio frequency signal receiver comprises an antenna, a matching circuit, and a low noise amplifier. The antenna receives a first radio frequency signal. The matching circuit adjusts impedance thereof to transmit the first radio frequency signal as a second radio frequency signal without attenuation. The low noise amplifier amplifies the second radio frequency signal to generate a third radio frequency signal and comprises a first transistor, a second transistor, and a first resistor. The first transistor has a gate receiving the second radio frequency signal, and a source coupled to a ground voltage. The second transistor has a drain outputting the third radio frequency signal, and a gate coupled to a first reference voltage. The first resistor is coupled between a drain of the first transistor and a source of the second transistor.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a block diagram of a radio frequency signal receiver according to the invention;

FIG. 2 is a circuit diagram of a first embodiment of a low noise amplifier according to the invention;

FIG. 3 is a circuit diagram of a second embodiment of a low noise amplifier according to the invention;

FIG. 4 is a schematic diagram of a relationship between a voltage gain and a noise figure of the low noise amplifiers shown in FIGS. 2 and 3; and

FIG. 5 is a schematic diagram of power consumption of the low noise amplifiers shown in FIGS. 2 and 3.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

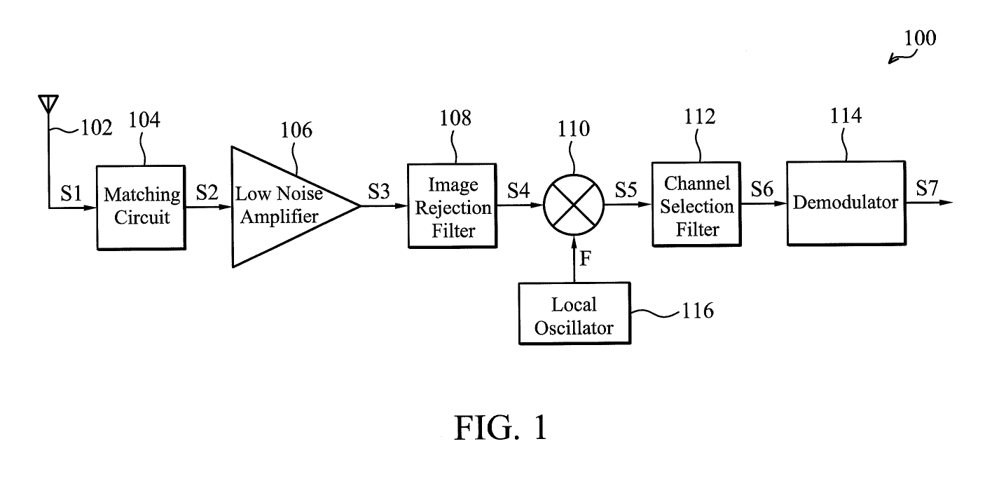

Referring to FIG. 1, a block diagram of a radio frequency signal receiver 100 according to the invention is shown. In one embodiment, the radio frequency signal receiver 100 comprises an antenna 102, a matching circuit 104, a low noise amplifier 106, an image rejection filter 108, a mixer 110, a local oscillator 116, a channel selection filter 112, and a demodulator 114. The antenna 102 receives a radio frequency signal S1. The impedance of the antenna 102 does not always match that of the low noise amplifier 106. When the impedance of the antenna 102 does not always match that of the low noise amplifier 106, a power of a signal transmitted between the antenna 102 and the low noise amplifier 106 is reduced. The matching circuit 104 therefore adjusts impedance thereof to transmit the radio frequency signal S1 as a radio signal frequency signal S2 to the low noise amplifier 106 without signal loss. The low noise amplifier 106 then amplifies in-band components of the radio frequency signal S2 to obtain a radio frequency signal S3.

The image rejection filter 108 then filters out image components from the radio frequency signal S3 to obtain a radio frequency signal S4. The local oscillator 116 generates a frequency signal F. The mixer 110 then mixes the radio frequency signal S4 with the frequency signal F to obtain a signal S5 with an increased frequency or a reduced frequency. The channel selection filter 112 then filters out out-band components from the signal S5 to obtain a signal S6. Finally, the demodulator 114 demodulates the signal S6 to obtain a data signal S7.

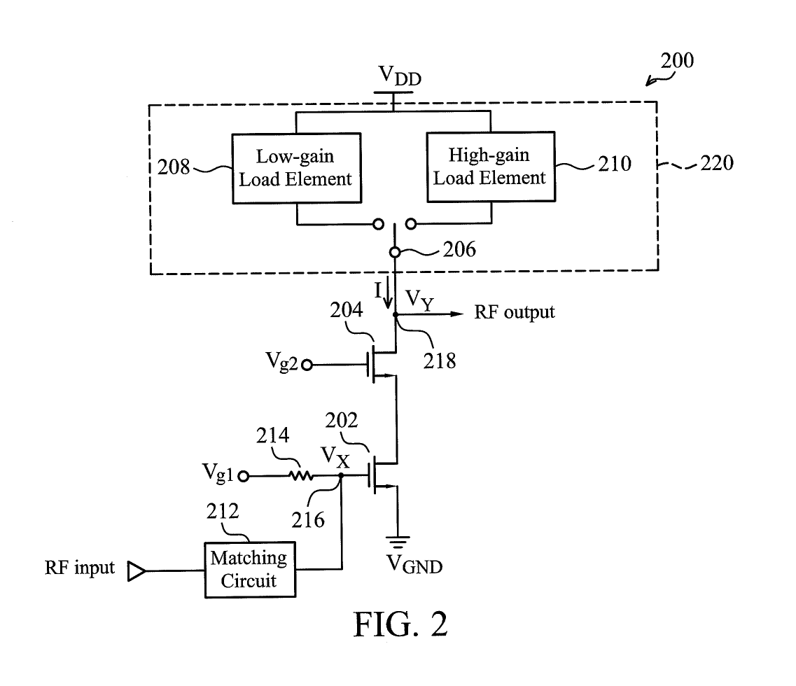

Referring to FIG. 2, a circuit diagram of a first embodiment of a low noise amplifier 200 according to the invention is shown. In the first embodiment, the low noise amplifier 200 comprises transistors 202 and 204, a switchable load element 220, and a resistor 214. The switchable load element 220 comprises a switch 206, a low-gain load element 208, and a high-gain load element 210. The NMOS transistor 202 has a source coupled to a ground voltage V_{GND}, a gate coupled to a reference voltage V_{g1} via the resistor 214, and a drain coupled to a source of the NMOS transistor 204. The NMOS transistor 204 has a gate coupled to a reference voltage V_{g2}, and a drain coupled to the switch 206.

The low-gain load element 208 and the high gain load element 210 are coupled between the switch 206 and a voltage source V_{DD}. The high-gain load element 210 has resistance higher than that of the low-gain load element 208. The switch 206 couples the drain of the NMOS transistor 204 to the low-gain load element 208 or the high gain load element 210 according to the gain required by the low noise amplifier 200. A radio frequency input signal received by an antenna is transmitted to a gate 216 of the NMOS transistor 202 through the matching circuit 212 as an input voltage Vx. A current I flowing through the transistors 202 and 204 is controlled by the voltage Vx on the gate node 216. When the voltage Vx increases, the current I, correspondingly increases. When a large current I flows through the switchable load element 220, a voltage drop across the switchable load element is induced, thus generating a radio frequency output signal V_{Y} on a drain 218 of the transistor 204. Thus, the voltage signal Vx on the gate node 216 of the transistor 202 is amplified by the low noise amplifier 200 to generate a radio frequency output signal V_{Y} on a drain node 218 of the transistor 204.

The low noise amplifier 200 shown in FIG. 2 can properly amplify a radio frequency input signal. The high-gain load element 210, the low-gain load element 208, and the NMOS transistors 202 and 204 are coupled between the voltage source V_{DD} and the ground voltage V_{GND}. When the low noise amplifier operates, if the input voltage signal Vx is a large input signal, the current I flowing through the high-gain load element 210, the low-gain load element 208, and the NMOS transistors 202 and 204 is large, inducing large power consumption.

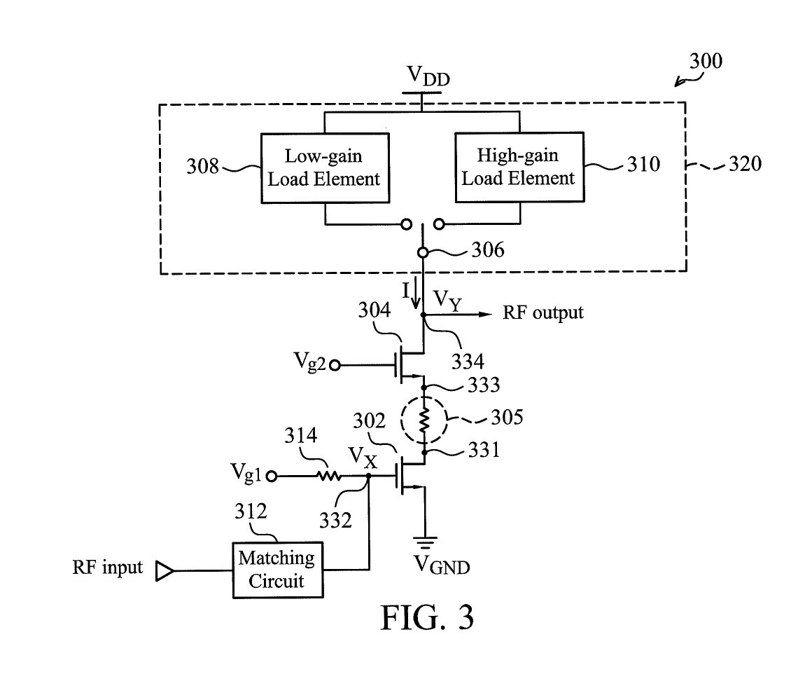

Referring to FIG. 3, a circuit diagram of a second embodiment of a low noise amplifier 300 according to the invention is shown. In the second embodiment, the low noise amplifier 300 comprises transistors 302 and 304, a switchable load element 320, and a resistor 314. The switchable load element 320 and the NMOS transistors 302 and 304 are coupled between a voltage source V_{DD} and a ground voltage V_{GND}. The NMOS transistor 302 is coupled between a node 331 and the ground voltage V_{GND}, and has a gate coupled to a node 332. The resistor 314 is coupled between the node 332 and a reference voltage V_{g1}. A radio frequency signal is transmitted to the node 332 via a matching circuit 312. A resistor 305 is coupled between a node 333 and the node 331.

The NMOS transistor 304 is couple between the nodes 334 and 333 and has a gate coupled to a reference voltage V_{g2}. The switchable load element 320 is coupled between a high voltage source V_{DD} and the node 334 and has switchable resistance. In one embodiment, the switchable load element 320 comprises a high-gain load element 310, a low-gain load element 308, and a switch 306. The resistance of the high-gain load element 310 is greater than that of the low-gain load element 308. The switch 306 couples the node 334 to the high-gain load element 310 or the low-gain load element 308 according to a gain of the low noise amplifier 300.

A radio frequency input signal received by an antenna is transmitted to the node 332 via the matching circuit 312 as an input voltage Vx. A current I flowing through the transistors 302 and 304 is controlled by the voltage Vx at the node 332. When the input voltage signal Vx is large, the current I increases. When a large current I flows through the switchable load element 320, the current I induces a large voltage drop across the switchable load element 320, generating a radio frequency output voltage V_{Y} at the node 334. The input voltage signal Vx on the gate 332 of the transistor 302 is therefore amplified to generate the radio frequency output voltage V_{Y} on the drain 334 of the transistor 304. In comparison with the low noise amplifier 200 of the first embodiment, the low noise amplifier 300 of the second embodiment further comprises a resistor 305 cascaded between the transistors 302 and 304. When the input voltage signal Vx is a large input signal, the current I flowing through the NMOS transistors 302 and 304 and the resistor 305 is reduced, thus lowering power consumption of the low noise amplifier 300.

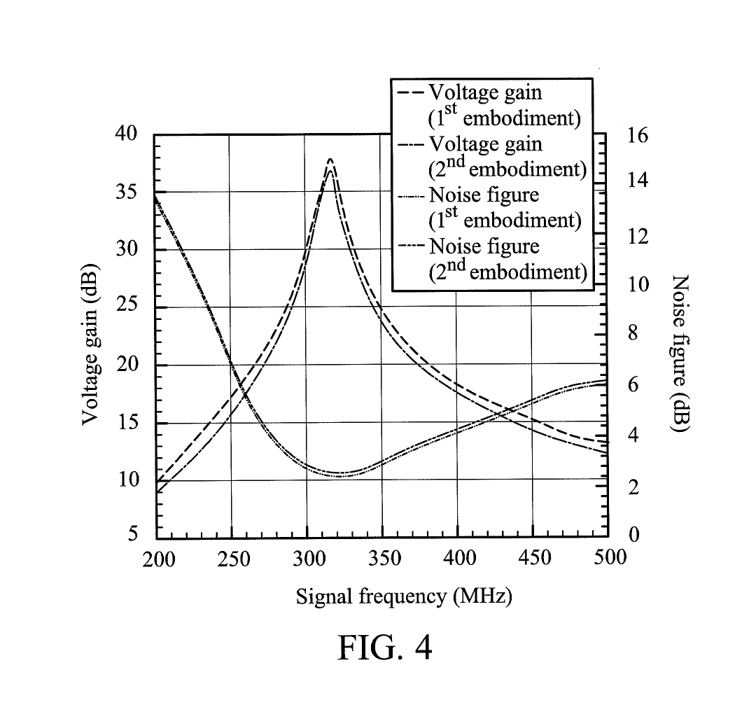

Referring to FIG. 4, a schematic diagram of a relationship between a voltage gain and a noise figure of the low noise amplifiers 200 and 300 shown in FIGS. 2 and 3 is shown. Assume that a frequency band of a radio frequency input signal at 355 MHz requires amplification. The low noise amplifiers 200 and 300 therefore must amplify the signal components with frequencies approximate to 315 MHz. Referring to FIG. 4, both the low noise amplifier 200 of the first embodiment and the low noise amplifier 300 of the second embodiment have gain peaks at the vicinity of 315 MHz, and both the low noise amplifier 200 of the first embodiment and the low noise amplifier 300 of the second embodiment have noise valleys of 315 MHz. Thus, even if a resistor 305 is added to the low noise amplifier 300, the low noise amplifier 300 of the second embodiment still has the same voltage gain and noise figure as those of the low noise amplifier 200 of the first embodiment. The low noise amplifier 300 therefore has the same performance as that of the low noise amplifier 200.

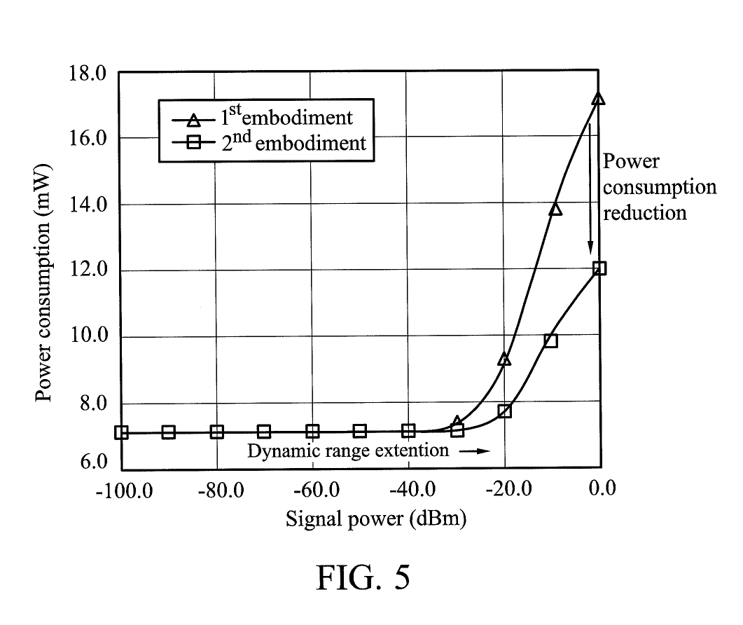

Referring to FIG. 5, a schematic diagram of power consumption of the low noise amplifiers 200 and 300 shown in FIGS. 2 and 3 is shown. Because the low noise amplifier 200 does not comprises a resistor coupled between the transistors 202 and 204, the current I flowing through the transistors 202 and 204 is large, inducing high power consumption. Thus, batteries supplying power to the low noise amplifier 200 have a short lifespan. On the contrary, because the low noise amplifier 300 comprises a resistor 305 coupled between the transistors 302 and 304, the current I flowing through the transistors 302 and 304 is small, inducing low power consumption. Thus, batteries supplying power of the low noise amplifier 300 have a long lifespan.

Referring to FIG. 5, when the radio frequency input signal has large signal power, the power consumption of the low noise amplifier is reduced by a large amount. The batteries of a portable device comprising the low noise amplifier 300 of the second embodiment, therefore have longer lifespan, and the dynamic range of the low noise amplifier 300 is therefore extended. In addition, the low noise amplifier 300 of the second embodiment has a longer dynamic range than that that of the low noise amplifier 200 of the first embodiment. Thus, the low noise amplifier 300 of the second embodiment can reduce power consumption without degrading signal quality.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A low noise amplifier, comprising:
a first transistor having a gate to receive a radio frequency input signal, wherein the source of the first transistor is coupled to a ground voltage;
a second transistor having a drain to output a radio frequency output signal, and wherein the gate of the second transistor is coupled to a first reference voltage; and
a first resistor coupled between the drain of the first transistor and the source of the second transistor.

2. The low noise amplifier as claimed in claim 1, wherein the low noise amplifier further comprises:
a switchable load element coupled between a voltage source and the drain of the second transistor, wherein the resistance of the switchable load element is adjustable.

3. The low noise amplifier as claimed in claim 2, wherein the switchable load element further comprises:
a high-gain load element coupled between the voltage source and a first node, wherein the high-gain load element has a high-resistance load;
a low-gain load element coupled between the voltage source and a second node, wherein the high-gain load element has a low-resistance load; and
a switch element coupled to the drain of the second transistor for controlling the conducting path from the drain of the second transistor to the first node or the second node.

4. The low noise amplifier as claimed in claim 1, wherein the low noise amplifier further comprises:
a second resistor couple between a second reference voltage and the gate of the first transistor, and
a matching circuit for receiving the radio frequency input signal, and adjusting impedance thereof to transmit the radio frequency input signal to the gate of the first transistor.

5. The low noise amplifier as claimed in claim 1, wherein the first transistor is an NMOS transistor.

6. The low noise amplifier as claimed in claim 1, wherein the second transistor is an NMOS transistor.

7. A low noise amplifier, comprising:
a first transistor coupled between a first node and a ground voltage, wherein the gate of the first transistor is coupled to a second node for receiving a radio frequency input signal;
a first resistor coupled between the first node and a third node;
a second transistor coupled between a fourth node and the third node, wherein the gate of the second transistor is coupled to a first reference voltage, wherein the fourth node outputs a radio frequency output signal; and
a switchable load element coupled between a voltage source and the fourth node, wherein the impedance of the switchable load element is adjustable.

8. The low noise amplifier as claimed in claim 7, wherein the low noise amplifier further comprises:
a second resistor couple between a second reference voltage and the second node, and
a matching circuit for receiving the radio frequency input signal, and adjusting impedance thereof to transmit the radio frequency input signal to the second node.

9. The low noise amplifier as claimed in claim 7, wherein the switchable load element further comprises:
a high-gain load element coupled between the voltage source and a fifth node, wherein the high-gain load element has a high-resistance load;
a low-gain load element coupled between the voltage source and a sixth node, wherein the high-gain load element has a low-resistance load; and
a switch element coupled the fourth node to switch the fifth node or the sixth node.

10. The low noise amplifier as claimed in claim 7, wherein the first transistor is an NMOS transistor.

11. The low noise amplifier as claimed in claim 7, wherein the second transistor is an NMOS transistor.

12. A radio frequency signal receiver, comprising:
an antenna for receiving a first radio frequency signal;
a matching circuit for adjusting impedance thereof to transmit the first radio frequency signal as a second radio frequency signal without attenuation; and
a low noise amplifier for amplifying the second radio frequency signal to generate a third radio frequency signal;
wherein the low noise amplifier including a first transistor with a gate for receiving the second radio frequency signal, and a source coupled to a ground voltage;
wherein the low noise amplifier including a second transistor with a drain outputting the third radio frequency signal, and a gate coupled to a first reference voltage;
wherein the low noise amplifier including a first resistor coupled between a drain of the first transistor and a source of the second transistor.

13. The radio frequency signal receiver as claimed in claim 12, wherein the low noise amplifier further comprises:
a switchable load element coupled between a voltage source and the drain of the second transistor, wherein the resistance of the switchable load element is adjustable.

14. The radio frequency signal receiver as claimed in claim 13, wherein the switchable load element further comprises:
a high-gain load element coupled between the voltage source and a first node, wherein the high-gain load element has a high-resistance load;
a low-gain load element coupled between the voltage source and a second node, wherein the high-gain load element has a low-resistance load; and
a switch element coupled to the drain of the second transistor to switch the first node or the second node.

15. The radio frequency signal receiver as claimed in claim 12, wherein the low noise amplifier further comprises:
a second resistor coupled between a second reference voltage and the gate of the first transistor.

16. The low noise amplifier as claimed in claim 12, wherein the first transistor is an NMOS transistor.

17. The low noise amplifier as claimed in claim 12, wherein the second transistor is an NMOS transistor.

18. The radio frequency signal receiver as claimed in claim 12, wherein the radio frequency signal receiver further comprises:
an image rejection filter for removing mirror images of the third radio frequency signal to obtain a fourth radio frequency signal;
a local oscillator for generating a frequency signal; and
a mixer for mixing the fourth radio frequency signal and the frequency signal to generate a fifth signal.

19. The radio frequency signal receiver as claimed in claim 18, wherein the radio frequency signal receiver further comprises:
a channel selection filter for removing out-of-band components from the fifth signal to obtain a sixth signal; and
a demodulator for demodulating the sixth signal to obtain a data signal.
